(19) United States
(12) Patent Application Publication
(10) Pub. No.: US 2012/0199175 A1
(43) Pub. Date: Aug. 9, 2012

(54) Articulating a Solar Energy System

(75) Inventor: Ross Koningstein, Menlo Park, CA (US)

(73) Assignee: GOOGLE INC., Mountain View, CA (US)

(21) Appl. No.: 13/023,307

(22) Filed: Feb. 8, 2011

(51) Int. Cl. H01L 31/052; F24J 2/52; F24J 2/38; F16H 57/08; F16H 13/06

(52) U.S. Cl. 136/246; 475/331; 475/149; 475/183; 126/606

(57) ABSTRACT

A solar energy system drive apparatus includes: a rotor including a first circumferential surface and having a first radial dimension from a center axis of the rotor; a stator that is axially aligned with the rotor about the center axis and includes a second circumferential surface and having a second radial dimension from the center of the rotor, wherein the second radial dimension is different than the first radial dimension; and a plurality of planetary members arranged about the first and second circumferential surfaces of the rotor and stator respectively, wherein each of the planetary members has a stepped circumferential surface comprising a third surface and a fourth surface such that the third circumferential surface is in contact with the first circumferential surface and has a third radial dimension from a central planetary axis of the planetary member.

### TECHNICAL BACKGROUND

This disclosure relates to systems and methods for solar energy system management.

### BACKGROUND

Solar energy management, collection, and use can often help alleviate energy problems around the world. In particular, solar energy systems (e.g., photovoltaic (“PV”) systems) that generate electrical energy from solar energy can reduce dependence on fossil fuels or other power generation techniques. Additionally, solar energy may be used to generate heat that can subsequently be used in power generation systems. In some cases, solar energy collection systems may include multiple heliostats that reflect solar energy to a receiver. The receiver may then use the reflected solar energy for one or more purposes. In some instances, heliostats are tracking mirrors, which reflect and focus sunlight onto a distant target, such as the receiver.

Heliostats typically move precisely and slowly throughout the day to track the sun. Heliostats must also be very stable when acted upon by external forces, especially wind, otherwise they can direct light off-target, reducing field efficiency. Thus, the drive-mechanism for heliostats must produce a slow, precise, high-torque rotation. In some cases, these requirements are often met by multi-stage gearboxes with high reduction ratios, torsional stiffness, and minimal backlash. Such gearboxes, however, can be notoriously expensive. Further, such precise mechanisms often require substantial protection from environmental elements, such as dust, rain, moisture, and otherwise, e.g., requiring a hermetically sealed enclosure in order to operate correctly over time.

### SUMMARY

In one general embodiment, a drive apparatus includes: a rotor including a first circumferential surface and having a first radial dimension from a center axis of the rotor; a stator that is axially aligned with the rotor about the center axis and includes a second circumferential surface and having a second radial dimension from the center of the rotor, wherein the second radial dimension is different than the first radial dimension; a plurality of planetary members arranged about the first and second circumferential surfaces of the rotor and stator respectively, wherein each of the planetary members has a stepped circumferential surface comprising a third surface and a fourth surface such that the third circumferential surface is in contact with the first circumferential surface and has a third radial dimension from a central planetary axis of the planetary member; and the fourth circumferential surface is in contact with the second circumferential surface and has a fourth radial dimension from the planetary axis of the planetary member that is different than the third radial dimension; and a driver configured to rotate the plurality of planetary members about the center axis, wherein each planetary member rotates about the member's planetary axis through contact between the second circumferential surface of the stator and the fourth circumferential surface of the planetary member and wherein said rotation of the planetary members imparts rotation of the rotor about the center axis through contact between the third circumferential surfaces of the planetary members and the first circumferential surface of the rotor.

In another general embodiment, a method for operating a solar energy collection system includes: rotating a plurality of planetary members about a first circumferential surface of a stator that is axially aligned about a central axis with a rotor that has a second circumferential surface, the stator and the rotor having different radial dimensions, each of the planetary members includes a stepped circumferential surface comprising a third circumferential surface and a fourth circumferential surface at different radial distances from a central planetary axis of the planetary member, wherein the third circumferential surface is in contact with the first circumferential surface of the stator and each planetary member rotates about the central planetary axis at a first rotational speed while the planetary member rotates about the stator; imparting a torque to the rotor during rotation of the plurality of planetary members about their respective planetary axes, the second circumferential surface of the rotor in contact with the fourth circumferential surfaces of the plurality of planetary members; rotating the rotor about the central axis in response to the torque applied to the rotor from the plurality of planetary members at a second rotational speed that is less than the first rotational speed; and rotating at the second rotational speed a solar energy member that is coupled to the rotor, the solar energy member having a surface facing toward the Sun, wherein solar rays from the Sun are incident on the surface.

In another general embodiment, a solar energy system includes: a solar energy member having a first surface facing toward the Sun, wherein solar rays from the Sun are incident on the first surface; a drive assembly coupled to the solar energy member, the drive assembly including a rotor having a first circumferential surface and having a first radial dimension from a center axis at a center of the rotor; a stator that is axially aligned with the rotor about the center axis, the stator having a second circumferential surface and having a second radial dimension from the center axis, wherein the second radial dimension is different than the first radial dimension; a plurality of planetary members arranged about the first and second circumferential surfaces of the rotor and stator respectively, wherein each of the planetary members has a stepped circumferential surface including a third surface and a fourth surface such that the third circumferential surface is in contact with the first circumferential surface and has a third radial dimension from a central planetary axis of the planetary member; and the fourth circumferential surface is in contact with the second circumferential surface and has a fourth radial dimension from the planetary axis of the planetary member that is different than the third radial dimension; and a driver configured to rotate the plurality of planetary members about the center axis, wherein each planetary member rotates about the member's planetary axis through contact between the second circumferential surface of the stator and the fourth circumferential surface of the planetary member and wherein said rotation of the planetary members imparts rotation of the rotor about the center axis through contact between the third circumferential surfaces of the planetary members and the first circumferential surface of the rotor. The system also includes a controller configured to control movement of the solar energy member with the drive assembly in accordance with movement of the Sun.

In one or more specific aspects of one or more of the general embodiments, at least one of the contact between the second circumferential surface of the stator and the fourth circumferential surface of the planetary member, and the contact between the third circumferential surfaces of the planetary members and the first circumferential surface of the rotor may include frictional contact.

In one or more specific aspects of one or more of the general embodiments, at least one of the contact between the second circumferential surface of the stator and the fourth circumferential surface of the planetary member and the contact between the third circumferential surfaces of the planetary members and the first circumferential surface of the rotor may include geared contact.

In one or more specific aspects of one or more of the general embodiments, the driver may be coupled to at least one of the planetary members.

In one or more specific aspects of one or more of the general embodiments, the system may further include a harness assembly including: at least one substantially rigid member connecting axles disposed through respective centers of two planetary members; and a biasing member connecting axles disposed through respective centers of two planetary members, wherein the biasing member urges the axles together.

In one or more specific aspects of one or more of the general embodiments, the driver may be coupled to the harness assembly and configured to rotate the harness assembly about the center axis to rotate the planetary members about the center axis.

In one or more specific aspects of one or more of the general embodiments, the biasing member may include a spring.

In one or more specific aspects of one or more of the general embodiments, the harness assembly may include first and second plates having centers aligned with the center axis, and wherein the rotor and stator are sandwiched between the first and second plates.

In one or more specific aspects of one or more of the general embodiments, at least one of the first and second plates may include a circumferential surface having a geared surface.

In one or more specific aspects of one or more of the general embodiments, the system may further include a gear coupled to the driver and interfacing the geared surface, wherein the gear is configured to transfer rotational force from the driver to the one of the first and second plates through the geared surface.

In one or more specific aspects of one or more of the general embodiments, the first and second plates may include a circumferential surface in frictional contact with the planetary member such that rotation of the plate causes rotation of the planetary member about the member's central planetary axis.

In one or more specific aspects of one or more of the general embodiments, the plurality of planetary members may include three planetary members.

In one or more specific aspects of one or more of the general embodiments, at least one of the rotor or stator may be made of or include a formed concrete disk.

In one or more specific aspects of one or more of the general embodiments, at least one of the rotor or stator contact surfaces may include a vehicular tire tread.

In one or more specific aspects of one or more of the general embodiments, the driver may be an electric motor.

In one or more specific aspects of one or more of the general embodiments, the second radial dimension may be smaller than the first radial dimension by a predetermined differential, and the fourth radial dimension may be larger than the third radial dimension by the predetermined differential.

In one or more specific aspects of one or more of the general embodiments, the first radial dimension may be smaller than the second radial dimension by a predetermined differential, and the third radial dimension may be larger than the fourth radial dimension by the predetermined differential.

In one or more specific aspects of one or more of the general embodiments, the predetermined differential may be approximately 0.1 inches; and the third radial dimension may be approximately 3 inches; and the second radial dimension may be between approximately 24 inches and approximately 36 inches.

In one or more specific aspects of one or more of the general embodiments, the system may include a bearing disposed between the rotor and the stator.

In one or more specific aspects of one or more of the general embodiments, the system may further include a spider assembly having: multiple spokes coupled to axles disposed through respective centers of two planetary members; and a web member coupled to the spokes and having an aperture operable to allow a shaft rigidly coupled to the rotor to pass through.

In one or more specific aspects of one or more of the general embodiments, imparting a torque to the rotor during rotation of the plurality of planetary members about their respective planetary axes may include imparting a torque to the rotor during rotation of the plurality of planetary members about their respective planetary axes through frictional contact between the second and fourth circumferential surfaces.

In one or more specific aspects of one or more of the general embodiments, imparting a torque to the rotor during rotation of the plurality of planetary members about their respective planetary axes may include imparting a torque to the rotor during rotation of the plurality of planetary members about their respective planetary axes through geared contact between the second and fourth circumferential surfaces.

In one or more specific aspects of one or more of the general embodiments, rotating a plurality of planetary members about a first circumferential surface of a stator that is axially aligned about a central axis with a rotor that has a second circumferential surface may include: rotating a harness assembly coupled to at least one of the planetary members about the central axis, the harness assembly having at least one substantially rigid member connecting axles disposed through respective centers of two planetary members; and a biasing member connecting axles disposed through respective centers of two planetary members, wherein the biasing member urges the axles together; and rotating, in response to the rotation of the harness assembly, at least one of the planetary members about the central axis.

In one or more specific aspects of one or more of the general embodiments, rotating a harness assembly coupled to at least one of the planetary members about the central axis may include: rotating at least one of first and second plates having centers aligned with the central axis, the rotor and stator sandwiched between the first and second plates.

In one or more specific aspects of one or more of the general embodiments, rotating, in response to the rotation of the harness assembly, at least one of the planetary members about the central axis may include imparting a torque to the planetary member through frictional contact between the at least one of the first and second plates and the planetary member.

In one or more specific aspects of one or more of the general embodiments, rotating, in response to the rotation of the harness assembly, at least one of the planetary members about the central axis includes: imparting a torque to the planetary member through geared contact between the at least one of the first and second plates and the planetary member.

In one or more specific aspects of one or more of the general embodiments, rotating a plurality of planetary members about a first circumferential surface of a stator that is axially aligned about a central axis with a rotor that has a second circumferential surface may include rotating only one of the planetary members about its central planetary axis with a driver; imparting a torque on the other planetary members through contact between the respective third circumferential surfaces of the other planetary members and the first circumferential surface of the stator; and rotating the other planetary members about the central axis in response to the torque.

In one or more specific aspects of one or more of the general embodiments, the first surface of the solar energy member may be a reflective surface configured to reflect the solar rays toward a solar energy receiver.

In one or more specific aspects of one or more of the general embodiments, the first surface of the solar energy member may be a solar panel that includes one or more photovoltaic cells.

In one or more specific aspects of one or more of the general embodiments, the controller may be configured to control at least one of azimuthal movement of the solar energy member and elevational movement of the solar energy member.

In one or more specific aspects of one or more of the general embodiments, the drive assembly may be a first drive assembly configured to adjust position of the solar energy member in azimuth in response to commands received from the controller, the system further including a second drive assembly substantially identical to the first drive assembly and configured to adjust a position of the solar energy member in elevation in response to commands received from the controller.

In one or more specific aspects of one or more of the general embodiments, the drive assembly may be exposed to an outside environment during normal operation.

In one or more specific aspects of one or more of the general embodiments, the drive assembly may further include a spool coupled to the rotor, and the system further may include: a cable coupled to the spool at a first end and coupled to the solar energy member at a second end opposite the first end, wherein rotation of the rotor about the center axis causes rotation of the spool to effect one of reeling in a portion of the cable around the spool or releasing a portion of the cable from the spool such that the solar energy member is rotated based on the rotation of the spool.

In one or more specific aspects of one or more of the general embodiments, the controller may be configured to control the driver at a first angular speed to compensate for slippage between at least one of a frictional contact between the third circumferential surface and the first circumferential, and a frictional contact between the fourth circumferential surface and the second circumferential surface.

In another general embodiment, a drive apparatus includes: a rotor comprising a first circumferential surface and having a first radial dimension from a center axis of the rotor; a stator that is axially aligned with the rotor about the center axis and includes a second circumferential surface and having a second radial dimension from the center of the rotor, wherein the second radial dimension is different than the first radial dimension; a plurality of planetary members arranged about the first and second circumferential surfaces of the rotor and stator respectively, wherein each of the planetary members has an outer surface in contact with the first and second circumferential surfaces; and a driver configured to rotate the plurality of planetary members about the center axis, wherein each planetary member rotates about the member's planetary axis through contact between the second circumferential surface of the stator and the outer surface of the planetary member and wherein the rotation of the planetary members imparts rotation of the rotor about the center axis through contact between the outer surfaces of the planetary members and the first circumferential surface of the rotor. At least a portion of at least one of the plurality of planetary members is adapted to be substantially sealed against an outside environment during normal operation of the apparatus, and at least a portion of at least one of the rotor and stator are adapted to be exposed to the outside environment during normal operation of the apparatus.

In one or more specific aspects of one or more of the general embodiments, at least one of the planetary members may include an axle such that a portion of the axle is disposed through a bore of the planetary member, and the portion of the planetary member adapted to be substantially sealed against the outside environment comprises the portion of the axle disposed through the bore.

In one or more specific aspects of one or more of the general embodiments, the stator may be axially aligned with the rotor about the center axis such that the stator is mounted adjacent a bottom surface of the rotor.

In one or more specific aspects of one or more of the general embodiments, the first radial dimension from the center axis of the rotor may be greater than the second radial dimension from the center of the rotor.

In one or more specific aspects of one or more of the general embodiments, the rotor may include a conduit disposed on an upper surface of the rotor and adapted to direct a flow of fluid away from the center of the rotor.

In one or more specific aspects of one or more of the general embodiments, at least one of the contact between the second circumferential surface of the stator and the outer surfaces of the planetary members, and the contact between the first circumferential surface of the rotor and the outer surfaces of the planetary members may be frictional contact.

In one or more specific aspects of one or more of the general embodiments, at least one of the rotor and stator may be constructed of a moisture resistant material.

In one or more specific aspects of one or more of the general embodiments, all of the rotor and the stator may be adapted to be exposed to the outside environment during normal operation of the apparatus.

Various implementations of a solar energy system drive assembly according to the present disclosure may include one or more of the following features and/or advantages. For example, the drive assembly may provide a relatively high gear ratio to drive a solar energy member at precise rotational speeds potentially with high torque. Further, the drive assembly may be more efficiently manufactured from common materials without extensive machining as compared to conventional gear boxes. In addition, the drive assembly may be configured to rotate the solar energy member about an azimuthal axis, as well as an elevational axis, in order to track in response to the movement of the Sun. As another example, the drive assembly may operate with relatively little protection from environmental elements, and avoid the expense of having to hermetically seal the entire assembly into a housing.

These general and specific aspects may be implemented using a device, system or method, or any combinations of devices, systems, or methods. The details of one or more implementations are set forth in the accompanying drawings and the description below. Other features, objects, and advantages will be apparent from the description and drawings, and from the claims.

### DESCRIPTION OF DRAWINGS

FIG. 1 illustrates an example embodiment of a solar energy system including a drive assembly for rotating a solar energy member;

FIGS. 2A-2B illustrate top and side views of an example embodiment of a drive assembly;

FIG. 3 illustrates a side view of another example embodiment of a drive assembly;

FIG. 4 illustrates a side view of another example embodiment of a drive assembly;

FIGS. 5A-5B illustrate top and side views of another example embodiment of a drive assembly;

FIG. 6 illustrates another example embodiment of a solar energy system including a drive assembly for rotating a solar energy member;

FIG. 7 illustrates an example method for operating a solar energy system including a drive assembly for rotating a solar energy member;

FIGS. 8A-8B illustrate top and side views of another example embodiment of a drive assembly; and

FIG. 9 illustrates another example embodiment of a solar energy system including a drive assembly for rotating a solar energy member.

### DETAILED DESCRIPTION

In some embodiments, a drive assembly includes a fixed stator and a rotor free to rotate about a central axis coincident with the centers of the rotor and stator. The stator and rotor have distinct radial dimensions that differ by a predetermined amount. Multiple planetary members are arranged around the outer circumferential surfaces of the rotor and stator. Each of the planetary members includes a stepped outer circumferential surface such that one portion of the planetary member having a first radial dimension is in contact with the fixed stator while a second portion of the member having a second radial dimension is in contact with the rotor. The first and second radial dimensions of the planetary members differ by the predetermined amount. Rotational movement imparted to at least one of the planetary members by a driver causes rotation of the members about the central axis, as well as about their planetary axes due to the contact with the fixed stator. Torque is imparted to the rotor by the contact between the planetary members and the rotor, thereby causing the rotor to rotate. The rotational speed of the planetary members may be much greater than that of the rotor, thereby providing a relatively high gear ratio for the rotor. In some implementations, such a drive assembly may be utilized with a solar energy system to, for example, rotate one or more solar energy members about an axis.

In some embodiments, a solar energy system includes a drive assembly, which rotates a solar energy member (e.g., heliostat mirror, PV panel) about an axis with an effectively high gear ratio. For instance, the drive assembly may include a fixed stator and rotor concentrically mounted about a bearing but with the stator and rotor having different radial dimensions. A number of planetary members are mounted about circumferential surfaces of the rotor and stator and have stepped circumferential surfaces (i.e., at least two different radial dimensions) to contactingly interface with the rotor and stator. As power is applied to a driver of the drive assembly to rotate the planetary members about a central axis of the rotor and stator, the contacting interface between the fixed stator and planetary members causes rotational movement of the planetary members about their respective planetary axes. During rotation of the planetary members about their respective planetary axes, torque is imparted to the rotor, causing rotational movement of the rotor about the central axis at a speed less than (and in some cases, much less than) the rotational speed of the planetary members about their respective planetary axes. A solar energy member rigidly coupled to the rotor may thus rotate at the reduced speed as well.

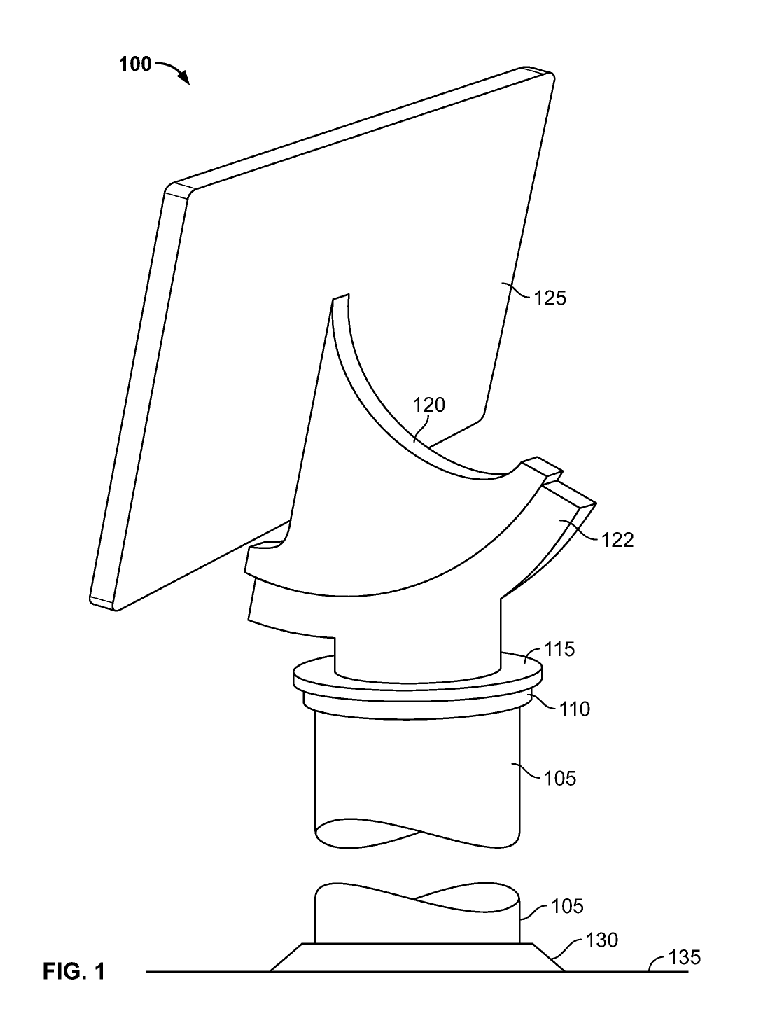

FIG. 1 illustrates an example embodiment of a solar energy system 100 including a drive assembly for rotating a solar energy member 125. In the illustrated embodiment, the solar energy system 100 includes a support member 105, a base 110 mounted on the support member 105, a drive assembly 115 mounted on the base 110, a solar energy member support 120 mounted on the drive assembly 115, and a solar energy member 125 coupled to the solar energy member support 120. Solar energy system 100, as illustrated, may collect or reflect solar energy from a remote source (e.g., the Sun or other solar energy source) while rotatably tracking the source under varying environmental conditions. For example, in some embodiments, the solar energy system 100 may be a heliostat that tracks (e.g., rotates to change its azimuth and/or pivots to change its elevation) the Sun in order to receive and reflect solar energy from the Sun to a solar energy collector (receiver) located remote from the heliostat. Alternatively, the solar energy system 100 may be a PV system where the solar energy member 125 is a PV panel that tracks the Sun to receive and collect solar energy to, for example, produce electricity. In any event, in some instances, the solar energy system 100 may be one of many systems 100 installed within a field or array that operate to collect and/or reflect solar energy provided by the remote source.

Changes in azimuth of the solar energy member 125 refers to rotation of the solar energy member 125 about a vertical axis, i.e., rotation about a vertical axis coincident with an axis through a centerline of the support member 105 (an “azimuthal axis”). Changes in elevation of the solar energy member 125 refers to changes in the angle between the direction the solar energy member 125 is pointing and a local horizontal plane, i.e., changes in the up-down angle (rotation about an “elevational axis”). The solar energy member 125 is mounted to the support 120 such that rotation about the azimuthal axis and rotation about the elevational axis within desired ranges to account for tracking the Sun throughout the course of day and throughout the days of a year are permitted. For example, in some implementations, a bearing at the interface 122 can operate to rotate the solar energy member 125 about the elevational axis.

The support member 105, as illustrated, is substantially vertical in orientation and may be mounted orthogonal to a terranean surface 135. The support member 105, in some embodiments, may be a wooden post, such as a cylindrical wooden post treated for exposure to varying environmental conditions (e.g., moisture, heat, and otherwise). Alternatively, the support member 105 may be any suitable material, such as stainless steel, painted ferrous steel, formed concrete, or otherwise, that may be secured in a substantially vertical position and support the solar energy member 125.

The illustrated support member 105 may be secured and/or attached to a footer 130 at one end of the member 105. In some embodiments, the footer 130 may be a concrete foundation installed to a particular depth below the terranean surface 135, thereby forming a cantilevered beam with the support member 105. Alternatively, however, the footer 130 may be supported by the terranean surface 135 without being installed or anchored below the surface. For example, the footer 130 may be a structure that can support the member 105 in a substantially vertical position under the weight of the solar energy member 125 (both static weight and dynamic weight during movement of the solar energy member 125). For example, the footer 130 can be a block or mass of concrete or other material (e.g., glass reinforced plastic) that includes an aperture or other recess for installation of the support member 105 therein. Further, in some embodiments, the footer 130 may not be installed to support the support member 105 and instead, the support member 105 may be inserted into a post hole formed in the terranean surface 135.

The base 110 is mounted or coupled to the support member 105 and, typically, provides a transitional member between the support member 105 and the drive assembly 115. In some embodiments, the base 110 may be eliminated or replaced with another form of transitional member.

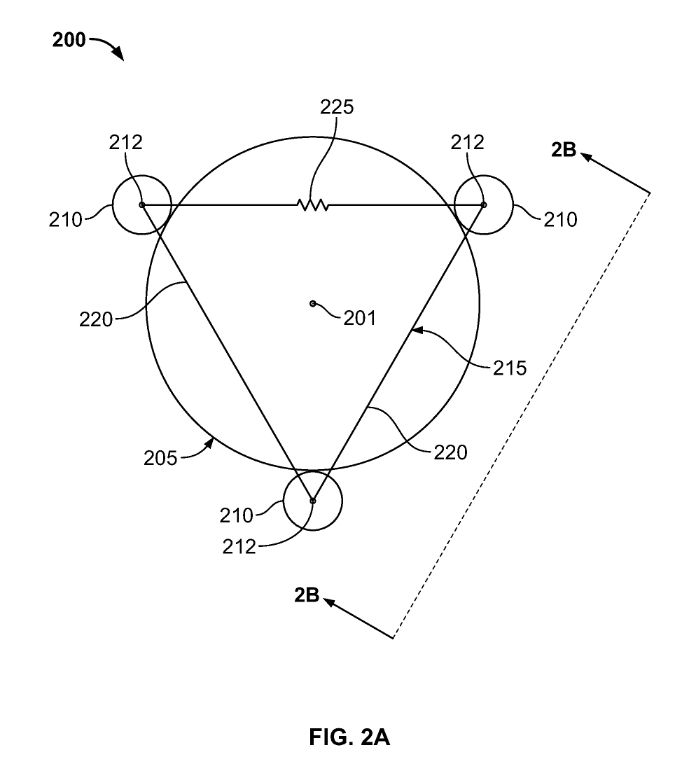

The drive assembly 115 is coupled to the support member 105 through the base 110 and, in the illustrated embodiment, may rotate one or more components of the solar energy system 100 in order to, for example, allow the solar energy member 125 to track the Sun during its azimuthal and elevational movement. For instance, in some embodiments, the drive assembly 115 (as more fully described in reference to FIGS. 2-7) may include a substantially fixed stator (e.g., a disc, cylindrical stator, or otherwise), a rotor (e.g., a disc, cylindrical stator, or otherwise) mounted concentrically on top of the stator and free to rotate with respect to the stator, and multiple (e.g., two or more, and preferably three or more) planetary members formed with stepped exterior, circumferential surfaces. Further, as described more fully below, the drive assembly 115 may include one or more drive mechanisms and a harness assembly for rotating the rotor and planetary members about respective axes of rotation. In some embodiments, the drive assembly 115 may, therefore, provide for controlled rotation to a predetermined gear ratio of one or more components of the solar energy system 100, such as the solar energy member 125.

Although illustrated enclosed in a container in FIG. 1, the drive assembly 115 may be substantially open to environmental conditions, such as rain, snow, dust, and otherwise, whether during operation or while idle. For example, one or more components of the drive assembly 115 (described in more detail below) may not be sealed (e.g., hermetically) in a housing or container. Alternatively, and as shown in FIG. 1 for example, the drive assembly 115 may be substantially contained in an enclosure (e.g., weatherproof container).

The solar energy member support 120 is mounted or coupled to the drive assembly 115 and provides structural support for the solar energy member 125. Although one embodiment of the solar energy member support 120 is illustrated in FIG. 1, the solar energy member support 120 may take many different configurations not shown here without departing from the scope of the present disclosure. In the illustrated embodiment, the solar energy member support 120 may be mounted to the drive assembly 115 through a common, rotatable shaft, such that rotation of the drive assembly 115 (or components of the drive assembly 115 such as a rotor) also rotates the shaft and, therefore, support 120. As the solar energy member support 120 may be rigidly coupled to the solar energy member 125, the solar energy member 125 may also rotate (e.g., about an azimuthal axis). In the illustrated embodiment, the solar energy member support 120 is mounted to the drive assembly 115 via the interface 122. The interface 122 may provide a cradle bearing (e.g., a goniometric bearing) that allows the support 120 to “rock” back and forth to adjust the elevational position of the solar energy member 125.

In the illustrated embodiment, the solar energy member 125 may be a heliostat mirror, which receives and reflects solar energy incident on a surface of the member 125 toward a remote location, such as a solar energy receiver. Alternatively, however, the solar energy member 125 may be another solar energy device, such as a PV panel. In any event, the solar energy member 125, typically, is substantially planar or can be curved and includes at least one surface that receives and reflects (i.e., a heliostat mirror) or receives and absorbs (i.e., a PV panel) solar energy. Although illustrated in FIG. 1 as a single, monolithic panel, the solar energy member 125 may be split into two (or more) equally or unequally-sized panels that together form the solar energy member 125.

FIGS. 2A-2B illustrate top and side views of various components of an example embodiment of a drive assembly 200. The drive assembly 200 can be configured to rotate a solar energy member, such as the solar energy member 125 shown in FIG. 1, although the drive assembly 200 can also be used in other implementations. In some embodiments, the illustrated components of drive assembly 200 may be used in or with the drive assembly 115 shown in FIG. 1. Generally, the drive assembly 200 may receive a rotational torque at a first rotational speed (i.e., angular speed, ω) and transform the first rotational speed to a second rotational speed according to a predetermined ratio. The second rotational speed, which in some embodiments may be less than, or much less than, the first rotational speed, may be applied to a rotor and/or shaft. The rotor and/or shaft may be coupled to, for example, a solar energy member in order to rotate the solar energy member at the second rotational speed.

As illustrated, the drive assembly 200 includes a cylindrical rotor 205 and a cylindrical stator 230 having centers coincident with a central axis 201; multiple planetary members 210 having respective planetary axes 212 arranged around respective circumferential surfaces of the rotor 205 and stator 230; and a harness assembly 215 coupled to the planetary members 210. The illustrated drive assembly 200 also includes a driver 240 coupled to one of the planetary members 240.

As illustrated, the rotor 205 and stator 230 are cylindrical disks having respective centerlines coincident with the central axis 201 therethrough. The rotor 205, as illustrated, has a radius Rr, which is slightly larger than a radius of the stator 230, which has a radius, Rs. The rotor 205 may be mounted concentrically on top of the stator 203 (e.g., via a shaft), and the rotor 205 is free to rotate with respect to the stator 230, which is rotationally fixed. The rotor 205 and stator 230 may be constructed to be very nearly the same size (i.e., (Rr−Rs)<<Rr). For example, the difference in radial dimensions of the rotor 205 and the stator 230 may be less than approximately 5% of Rr. In some aspects, one or both of the rotor 205 and the stator 230 may be formed, concrete discs, having relatively large tolerances (e.g., plus or minus 1 mm). Along with having such tolerances, one or both of the rotor 205 and the stator 230 may be formed from weather resistant (e.g., moisture resistant, thermal resistant) material, such that exposure to environmental conditions (during operation or otherwise) may not substantially affect the rotor 205 and stator 230.

In the illustrated embodiment, a bearing 235 is disposed between the rotor 205 and the stator 230. The bearing 235 may provide for reduced friction movement of the rotor 205 as it rotates with respect to the stator 230. For example, the bearing 235 may be a thrust bearing formed using matched circular grooves in the faces of the rotor 205 and the stator 230 with rollers (e.g., polyurethane balls) which roll in the grooves. Alternatively, or additionally, the bearing 235 may be a lubricating material that reduces a frictional force generated during rotation of the rotor 205.

The planetary members 210 are arranged around respective outer circumferential surfaces of the rotor 205 and the stator 230, and, as illustrated, have stepped circumferential outer surfaces such that an upper portion of a planetary member 210 has a smaller radial dimension than a radial dimension of a lower portion of the planetary member 210. That is, the planetary members 210 may be stepped cylindrically shaped members (solid, hollow or otherwise) with two, concentric steps. The steps have slightly different radii, Rpr and Rps, where, for example, Rpr is smaller than Rps. The difference between the radii of the steps may be equal or substantially equal to the difference in radial dimensions of the rotor 205 and the stator 230 (Rr and Rs, respectively). In the illustrated embodiment, the planetary members 210 are constructed such that Rps and Rpr are both much smaller than the radial dimensions of the rotor 205 and the stator 230 (i.e., Rpr<Rps<<Rr). For example, the planetary members may be less than approximately ¼ the radius of the rotor 205 and stator 230 and, in some aspects, much less. In some implementations, the planetary members 210 are wheels having a stepped outer surface as described above.

In the illustrated embodiment, each planetary member 210 includes a lower planetary member surface 216 and an upper planetary member surface 218. The surfaces 216 and 218 are circumferential and are opposed, respectively, with a stator circumferential surface 232 and a rotor circumferential surface 207. The lower planetary member surface 216 is in contact (e.g., frictional) with the stator circumferential surface 232, while the upper planetary member surface 28 is in contact (e.g., frictional) with the rotor circumferential surface 207. As discussed above, the lower planetary member surface 216 has a radial dimension, Rps, from the planetary axis 212, while the upper planetary member surface 218 has a radial dimension, Rpr, from the planetary axis 212.

As illustrated, each planetary member 210 includes an axle 214 disposed through the planetary axis 212 of the planetary member 210. In some implementations, the axle 214 may be sealed (e.g., hermetically) through the planetary member 210 such that moisture, dust, or other substance is substantially prevented from intrusion therein.

In the implementation shown, the drive assembly 200 also includes a harness assembly 215. The harness assembly 215 includes linkages 220 coupled to axles 214 of the planetary members 210. The harness assembly 215 also includes a biasing member 225 coupled between two of the planetary members 215. The biasing member 225, which, in some aspects, may be a spring, a bungee, or other biasing element, urges the axles 214 of the respective planetary members 210 together. The respective planetary members 210 may, therefore, be urged together to maintain contact of the planetary members 210 against the rotor 205 and stator 230. As illustrated, the harness assembly 215 is free to rotate with respect to both the stator 230 and the rotor 205 about the central axis 201.

As illustrated in FIG. 2B, the driver 240 is coupled to the axle 214 of one of the planetary members 210. While more than one of the planetary members 210 may be coupled to a driver (e.g., an electric motor) and driven (e.g., rotated) about its planetary axis 212, one driver 240 may be coupled to one planetary member 210 and utilized for operation of the drive assembly 200. In other implementations, there may be multiple drivers 240.

In operation, the driver 240 may rotate the planetary member 210 to which it is coupled, which in turn rotates the harness assembly 215. Alternatively, the driver may be configured to directly rotate the harness assembly 215 coupled to the planetary members 210, at a first rotational speed. In any event, the harness assembly 215 carries the planetary members 210 along as it rotates, keeping the planetary members 210 in firm contact with the rotor 205 and stator 230 (i.e., keeping contact between the upper planetary member surface 218 and rotor circumferential surface 207, and between the lower planetary member surface 216 and the stator circumferential surface 232). As the harness assembly 215 rotates about the central axis 201, the planetary members 210 also rotate about their own respective planetary axes 212 due to the rolling contact between the lower planetary member surface 216 and the fixed stator circumferential surface 232. As the planetary members 210 rotate, they are also in rolling contact with the rotor 205 and impart a torque to the rotor 210. Due to the difference in radial dimensions between rotor 205 and the stator 230 (Rr>Rs), the rotor 205 may be rotated with the rotation of the harness assembly 215, but at a second rotational speed that is substantially reduced compared to the first rotational speed. Further, the rotor 205 may be rotated with a substantially-multiplied torque. The net result is an effective gear ratio, with the harness assembly 215 serving as an input and the rotor 205 serving as an output. While not shown, a shaft rigidly coupled to the rotor 205 will thus rotate at the second rotational speed as well. Further, any structure rigidly coupled to the shaft (directly or indirectly), such as a solar energy member, will also rotate at the second rotational speed.

In some aspects, the effective gear ratio described above may be predetermined and/or calculated with reference to the first rotational speed and the relative dimensions of the rotor 205, stator 230, and planetary members 210. For example, the second rotational speed may be calculated according to the following equation:

ω_{R}=GR*ω_{PM} [Equation 1],

where ω_{R} is the second rotational speed (i.e., the rotational speed of the rotor 205); GR is the gear ratio, and ω_{PM} is the first rotational speed (i.e., the rotational speed of the harness assembly 215 about the central axis 201). The gear ratio, GR, may be calculated according to the equation:

$$GR = \frac{E}{r + E} * \frac{R + r}{R} , \qquad [ Equation 2 ]$$

where E is the difference between the radial dimensions of the rotor 205 and the stator 230; R is the radial dimension, Rr, of the rotor 205; and r is the radial dimension of the upper planetary member surface 218, Rpr, of the planetary members 210.

In one embodiment, the dimensions may be as follows: R is approximately 12 inches; r is approximately 3 inches; and E is approximately 0.1 inches. Accordingly, the gear ratio, GR, according to Equation 2 is approximately 1/24 (e.g., with geared surfaces and close to this value with frictional contact surfaces). Given a steady state first rotational speed of the harness assembly 215, the second rotational speed may be calculated per Equation 1 above.

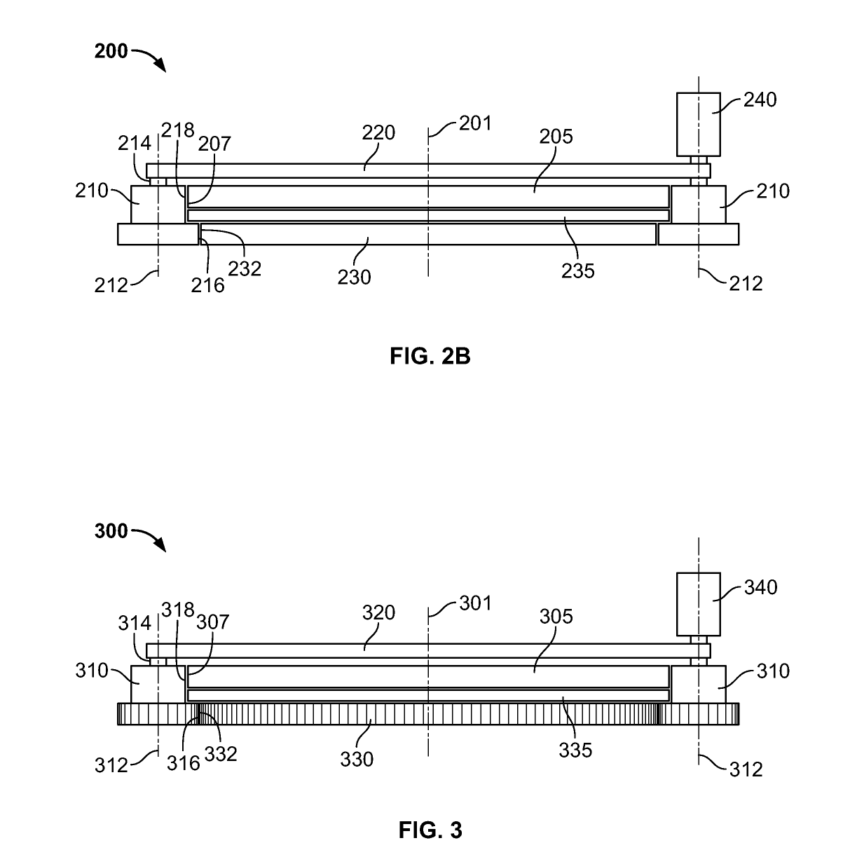

FIG. 3 illustrates a side view of another example embodiment of a drive assembly 300. In some implementations, the drive assembly can be used for rotating a solar energy member, such as the solar energy member 125 shown in FIG. 1 (or other solar energy members), although other uses for the drive assembly 300 are possible. As illustrated, the drive assembly 300 includes a cylindrical rotor 305 (with rotor circumferential surface 307) and a cylindrical stator 330 (with stator circumferential surface 332) having centers coincident with a central axis 301; multiple planetary members 310 having respective planetary axes 312 and axles 314 there through; and a harness assembly 315 with one or more linkages 320 coupled to the planetary members 310. The illustrated drive assembly 300 also includes a driver 340 coupled to one of the planetary members 340 and/or the harness assembly 315. The illustrated planetary members 310 include an upper planetary member surface 318 and a lower planetary member surface 316. Further, a bearing 335 may be disposed between the rotor 305 and the stator 330.

The foregoing components of the drive assembly 300 may be substantially similar to similarly named components illustrated in FIGS. 2A-2B. However, as illustrated, the stator circumferential surface 332 and lower planetary member surface 316 are geared surfaces that mesh together during rotation of the planetary members 310 about the stator 330. Thus, rather than utilizing a frictional contact between surfaces 316 and 332 (for example, as shown in FIG. 2B), a geared interface is utilized. In addition, although not shown in FIG. 3, a geared interface may be utilized between the planetary members 310 and the rotor 305. For example, the upper planetary member surface 418 and rotor circumferential surface 407 may be geared (i.e., have gear teeth disposed about the circumferential surfaces), such that torque is imparted to the rotor 305 by the planetary members 310 through the geared interface.

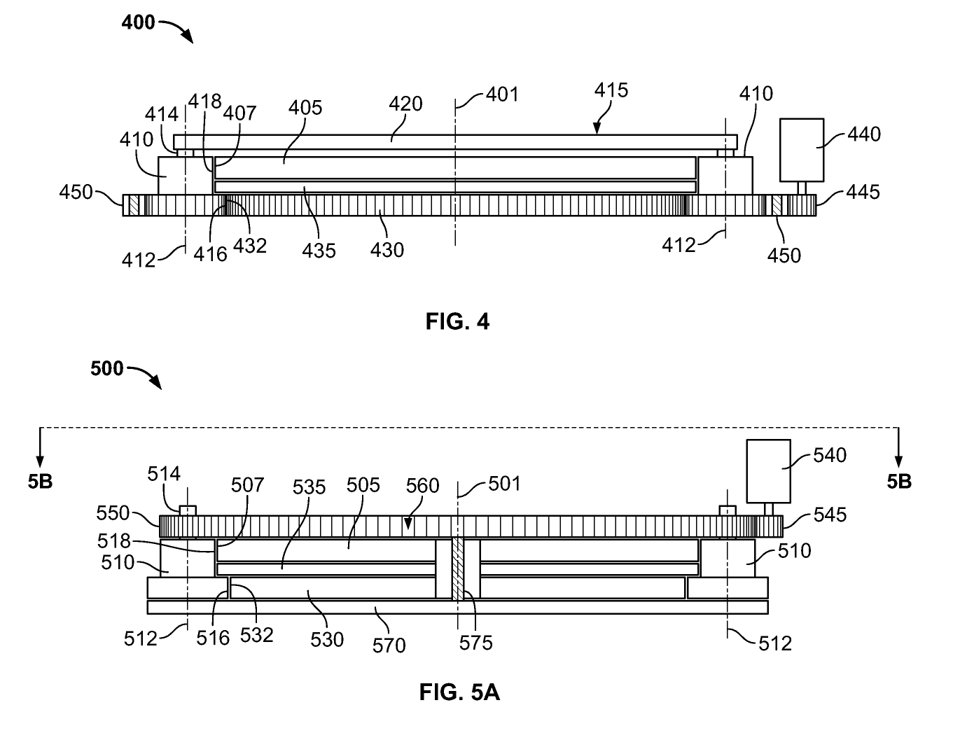

FIG. 4 illustrates a side view of another example embodiment of a drive assembly 400. In some implementations, the drive assembly 400 can be used for rotating a solar energy member, such as the solar energy member 125 (or other solar energy members), although other uses for the drive assembly 400 are possible. As illustrated, the drive assembly 400 includes a cylindrical rotor 405 (with rotor circumferential surface 407) and a cylindrical stator 430 (with stator circumferential surface 432) having centers coincident with a central axis 401; multiple planetary members 410 having respective planetary axes 412 and axles 414 therethrough; and a harness assembly 415 with one or more linkages 420 coupled to the planetary members 410. The foregoing components of the drive assembly 400 may be substantially similar to similarly named components illustrated in FIGS. 2A-2B and 3. As illustrated, the stator circumferential surface 432 and lower planetary member surface 416 are geared surfaces that mesh together during rotation of the planetary members 410 about the stator 430. Thus, rather than utilizing a frictional contact between surfaces 416 and 432, a geared interface is utilized.

The illustrated drive assembly 400 also includes a driver 440 and a chain drive 450. As illustrated, the chain drive 450 interfaces with the lower planetary member surface 416 (which is geared) and is disposed about the planetary members 410. The driver 440 (e.g., an electric motor) includes a gear 445 disposed on a shaft of the driver 440, which may rotate as the shaft of the driver 440 rotates. As the gear 445 also interfaces with the chain drive 450, rotation of the gear 445 will impart rotation to the chain drive 450, and thus, the planetary members 410. Alternatively, in some embodiments, the chain drive 450 may be eliminated and the gear 445 may interface directly with the lower planetary member surface 416.

In operation, the driver 440 can be powered (e.g., by electricity or otherwise) to rotate the gear 445, which in turn rotates the planetary members 410 (e.g., through the chain drive 450 or otherwise) at a first rotational speed about the central axis 401. As described above, as the planetary members 410 rotate about their respective planetary axes 412 and the central axis 401, a torque is imparted to the rotor 405, thereby causing the rotor 405 to rotate at a second rotational speed. The second rotational speed, as described above, is a function of the first rotational speed and the specific gear ratio, GR.

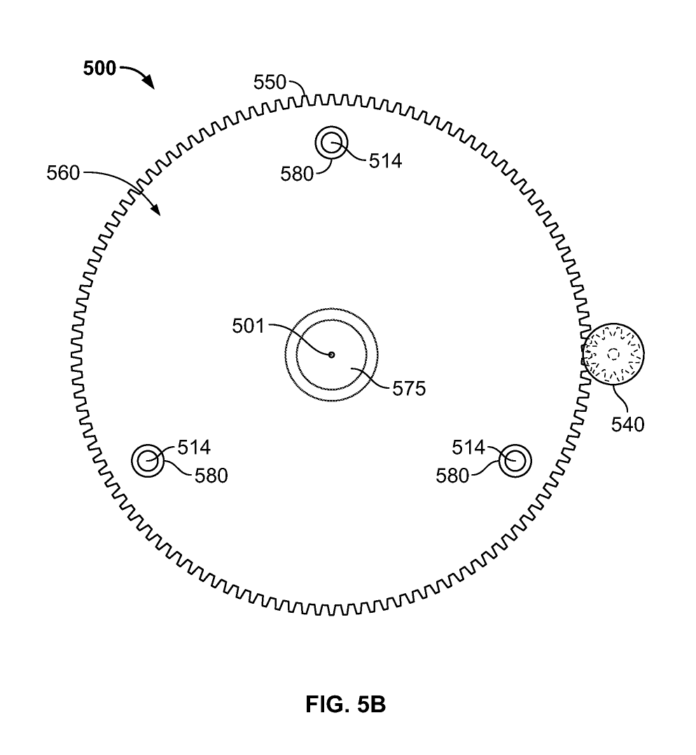

FIGS. 5A-5B illustrate top and side views, respectively, of another example embodiment of a drive assembly 500. In some implementations, the drive assembly 500 can be used for rotating a solar energy member, such as solar energy member 125 or other solar energy member, although other uses of the drive assembly 500 are possible. As illustrated, the drive assembly 500 includes a cylindrical rotor 505 (with rotor circumferential surface 507) and a cylindrical stator 530 (with stator circumferential surface 532) having centers coincident with a central axis 501; multiple planetary members 510 having respective planetary axes 512 and axles 514 therethrough; and a bearing 535 disposed between the rotor 505 and the stator 530. The foregoing components of the drive assembly 500 may be substantially similar to similarly named components illustrated in FIGS. 2A-2B.

In addition, drive assembly 500 includes a driver 540 coupled to a gear 545, a top plate 560 disposed on top of the rotor 505, a bottom plate 570 disposed below the stator 530, and a shaft 575 connecting the top and bottom plates 560 and 570 through apertures formed in the rotor 505, the stator 530, and the bearing 535. As illustrated, the top plate 560 is a substantially cylindrical disc with a center coincident with the central axis 501 and having apertures 580 allowing the axles 514 of the planetary members 510 to protrude upwardly therethrough. In some embodiments, the apertures 580 may be formed such that incremental radial movement (e.g., about 1 centimeter) of the axles 514 (e.g., towards the central axis 501) is allowed. The top plate 560 and apertures 580 may otherwise constrain the axles 514 to rotate about the central axis 501 during rotational movement of the top plate 560 (as explained below).

The top plate 560 includes an outer circumferential surface 550, which, as illustrated, is geared. The outer circumferential surface 550 thus meshes with the gear 545 such that rotational movement of the gear 545 (e.g., during operation of the driver 540) is imparted to the top plate 560. Alternatively, the outer circumferential surface 550 and gear 545 may be formed for frictional contact therebetween.

The bottom plate 570, as illustrated, 560 is a substantially cylindrical disc with a center coincident with the central axis 501 and is rigidly coupled to the top plate 560 via the shaft 575. The bottom plate 570, as illustrated, may provide increased structural rigidity to the drive assembly 500 and, in some aspects, may help seal the drive assembly 500 against environmental conditions. During rotational movement of the top plate 560, therefore, the bottom plate 570 also rotates with the same rotational velocity. Of course, in some embodiments, the bottom plate 570 may have a geared outer surface and the driver 540 may drive the bottom plate 570 via the gear 545 (e.g., in place of or in addition to driving the top plate 560).

In one example operation, the driver 540 rotates the gear 545, which interfaces with the outer circumferential surface 550. The rotation of the gear 545 rotates the top plate 560 at a first rotational speed. As the top plate 560 rotates about the central axis 501, the axles 514 also rotate about the central axis 501 as they are rotationally urged by the top plate 560. As the axles 514 are rotatably urged around the central axis 501, the planetary members 510 are also rotated around the central axis 510 while in contact (e.g., frictional, geared, or otherwise) with the rotor 505 and the stator 530. In some aspects, the top plate 560 may also include a mechanism for pressing the planetary members 510 forcefully into contact with the stator 530 and the rotor 510, such as, for example, a spring or other source of elastic tension. As described above, as the planetary members 510 rotate about their respective planetary axes 512 in contact with the fixed stator 530, a torque is imparted by the planetary members 510 to the rotor 505. The imparted torque on the rotor 505 forcibly rotates the rotor 505 about the central axis at a second rotational speed that is different (i.e., lower and, preferably, much lower) than the first rotational speed. A structure rigidly coupled (directly or indirectly) with the rotor 505, such as a solar energy member, also rotates at the second rotational speed.

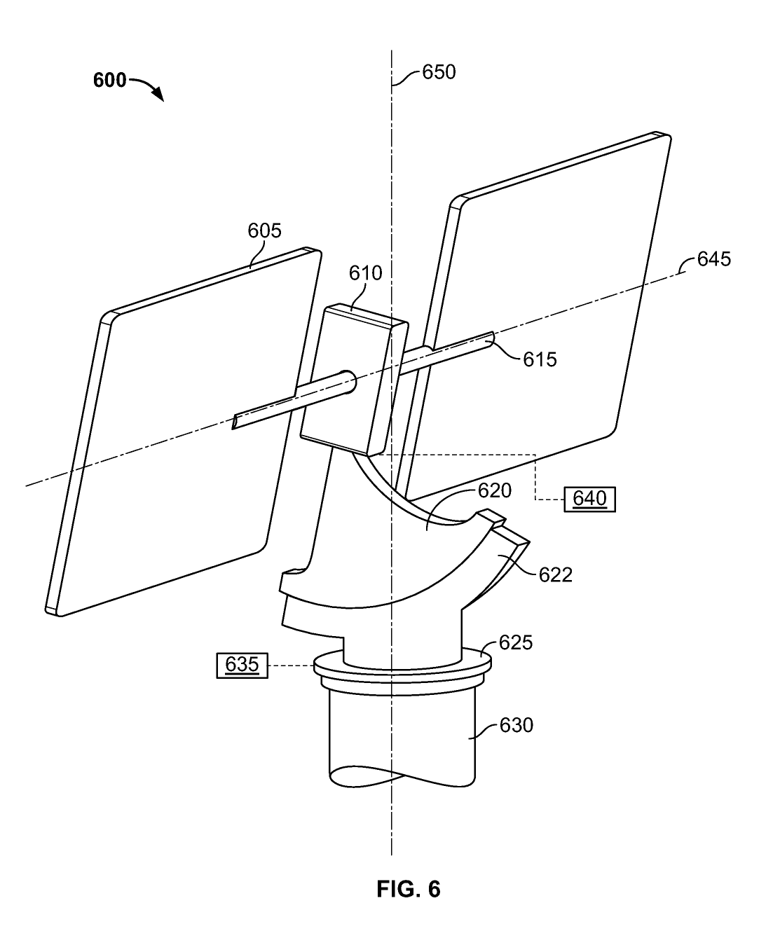

FIG. 6 illustrates another example embodiment of a solar energy system 600 including a drive assembly for rotating a solar energy member 605. In some embodiments, the solar energy system 600 may include two (or more) drive assemblies to rotate the solar energy system 600 about at least two axes of rotation. For example, system 600 includes a first drive assembly 625 that rotates the solar energy member 605 about an azimuthal axis 650 and a second drive assembly 610 that rotates the solar energy member 605 about an elevational axis 645. One or both of the drive assemblies 610 and 625 may be substantially similar to one of the drive assemblies described above with respect to FIGS. 2A-2B, 3, 4, and 5A-5B. For example, drive assembly 610 may be one of the drive assemblies described above but flipped on its side. Thus, a shaft 615 coupled to a rotor of the drive assembly 610 is coincident with the axis 645. Rotation of the shaft 615, therefore, rotates the solar energy member 605 through varying elevational positions. While illustrated as enclosed within a housing, either or both of the drive assemblies 610 and 625 may be exposed (substantially or completely) to an outdoor environment during operation.

As illustrated, the solar energy system 600 also includes a support member 630, a support 620, an interface 622, a first controller 635, and a second controller 640. The support member 630 and the support 620 may, in some embodiments, be substantially similar to the same components described in reference to FIG. 1. As illustrated, the solar energy member 605 is split down a centerline of the member 605 coincident with the azimuthal axis 650, with the second drive assembly 610 mounted between and coupled to first and second portions of the solar energy member 605. Alternatively, the solar energy member 605 may be divided into more portions, different sized portions, or left as a single panel. The solar energy member 605 may be flat as shown or may have a curved surface that faces toward the Sun.

The first controller 635 is communicably coupled with the first drive assembly 625 and operably controls the first drive assembly 625 to rotate the solar energy member 605 about the azimuthal axis 650. For example, the first controller 635 may receive and/or measure various data (e.g., Sun location, time of day, wind speed, solar receiver location, or otherwise) and algorithmically determine an optimal azimuthal position of the solar energy member 605. The first controller 635 may then transmit signals to the first drive assembly 625 to operate the assembly 625 (e.g., operate a driver of the drive assembly 625) to rotate the solar energy member 605 to the optimal azimuthal position.

In similar fashion, the second controller 640 is communicably coupled with the second drive assembly 610 and operably controls the second drive assembly 610 to rotate the solar energy member 605 about the elevational axis 645. For example, the second controller 640 may receive and/or measure various data (e.g., Sun location, time of day, wind speed, solar receiver location, or otherwise) and algorithmically determine an optimal elevational position of the solar energy member 605. The second controller 640 may then transmit signals to the second drive assembly 610 to operate the assembly 610 (e.g., operate a driver of the drive assembly 610) to rotate the solar energy member 605 to the optimal elevational position. In some implementations, the first controller 635 and the second controller 640 are implemented together as a single controller that is configured to carry out the operations described above.

While FIG. 6 shows one example embodiment of the solar energy system 600, others are within the scope of the present disclosure. For example, the solar energy system 600 may only include one of the two drive assemblies 610 and 625. Alternatively, there may be more than two drive assemblies; for example, there may be a separate drive assembly for each panel of the solar energy member 605. In addition, while two controllers 635 and 640 are shown, there may be fewer or more controllers operably controlling the drive assemblies 610 and 625. In addition, the controllers 635 and 640 may be located at the respective drive assemblies 625 and 610; at a remote location (e.g., at a facility designed to control an array of solar energy systems 600); or integral to the drive assemblies themselves, to name but a few locations. In some implementations, one or both of the controllers 635 and 640 provide signals to continuously adjust the position of the solar energy member 605. In other implementations, signals are provided at predetermined intervals (e.g., every 15 minutes). In other implementations, signals are provided at predetermined intervals to account for predictable conditions (e.g., the position of the Sun) and on an as-needed basis to account for unpredictable conditions (e.g., being moved off target by a wind force). Other techniques can be used to determine when and by how much to adjust the position of the solar energy member 605.

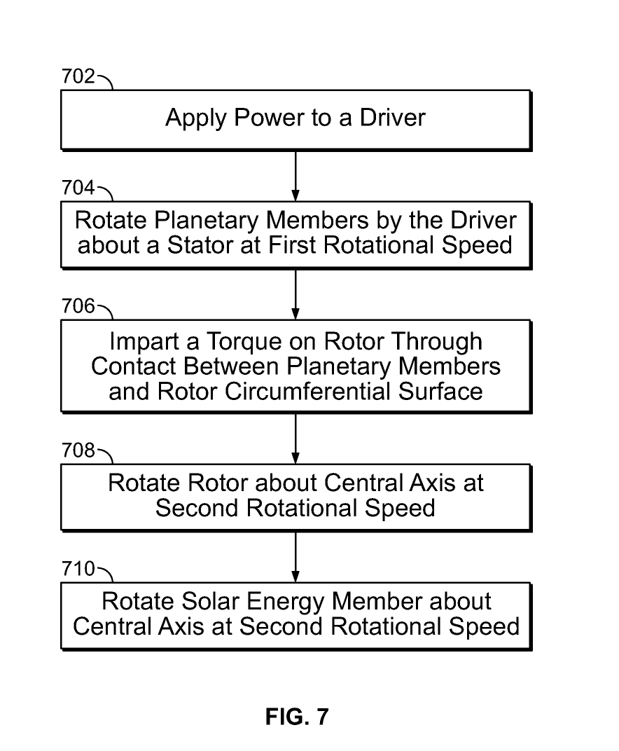

FIG. 7 illustrates an example method 700 for operating a solar energy system including a drive assembly for rotating a solar energy member. In some embodiments, method 700 may be used, for example, to operate solar energy system 100, solar energy system 600, or any other solar energy system. Method 700 may begin at step 702, when power is supplied to a driver of the solar energy system. In some embodiments, the driver, which may be similar, for example, to driver 240 (e.g., an electric motor) may receive a command to start from a controller. For instance, a controller, such as controller 635 or controller 640 shown in FIG. 6, may algorithmically determine that a solar energy member of the solar energy system may need to rotate (e.g., to track elevational or azimuthal movement of the Sun).

Next, the driver may rotate one or more planetary members of a drive assembly of the solar energy system about a stator at a first rotational speed at step 704. For example, as described above, the driver may directly rotate one planetary member (such as planetary member 210) about a central axis of the drive assembly, thereby generating rotational movement of the planetary members about their respective planetary axes while in contact (e.g., frictional, geared or otherwise) with the fixed stator. Alternatively, the driver may rotate a harness assembly coupled to the planetary members about the central axis of the drive assembly, thereby generating rotational movement of the planetary members about the central axis. In addition, the driver may rotate a plate coupled to the planetary members, as described above with respect to FIGS. 5A-5B. And as described more fully below, a driver may rotate a spider assembly coupled to the planetary members to generate rotational movement of the planetary members about a central axis.

In step 706, a torque is imparted to a rotor of the drive assembly through contact (e.g., frictional, geared, or otherwise) with the rotating planetary members. As described above, the rotor may be free to rotate relative to the stator, and may have a slightly larger radial dimension than the stator. The planetary members, therefore, may have a stepped cylindrical outer surface, such that contact between the planetary members and the rotor and stator is maintained during rotation of the planetary members about the central axis. As the planetary members rotate about their respective planetary axes and the stator, the torque may be imparted to the rotor by the rolling contact between the planetary members and rotor.

In step 708, the rotor may rotate about the central axis due to the imparted torque. As described above, the rotor rotates at a second rotational speed which is different (e.g., less and often much less) than the first rotational speed of the planetary members about their respective planetary axes. At step 710, the solar energy member rigidly coupled to the rotor (e.g., via a shaft) also rotates at the second rotational speed. In some embodiments, the driver may receive power for a set time duration in order to rotate the solar energy system a predetermined angular distance (e.g., elevationally or azimuthally). For instance, the controller may be pre-programmed with data regarding the second rotational speed as a function of the gear ratio (as described above) and an input speed of the driver (i.e., the first rotational speed); thus, the controller may be pre-programmed or may pre-determine an angular distance travelled of the solar energy member per time unit as a function of the first rotational speed. The controller may, therefore, pre-determine a time duration in which the driver is powered in order to meet a desired angular rotation distance of the solar energy member. Once power to the driver has been applied for the pre-determined time duration, the driver may be stopped, thereby stopping angular rotation of the solar energy member coupled to the rotor of the drive assembly. Of course, the foregoing is an example operation and other operations that accomplish desired angular movement of the solar energy member have been described herein and are within the scope of this disclosure.

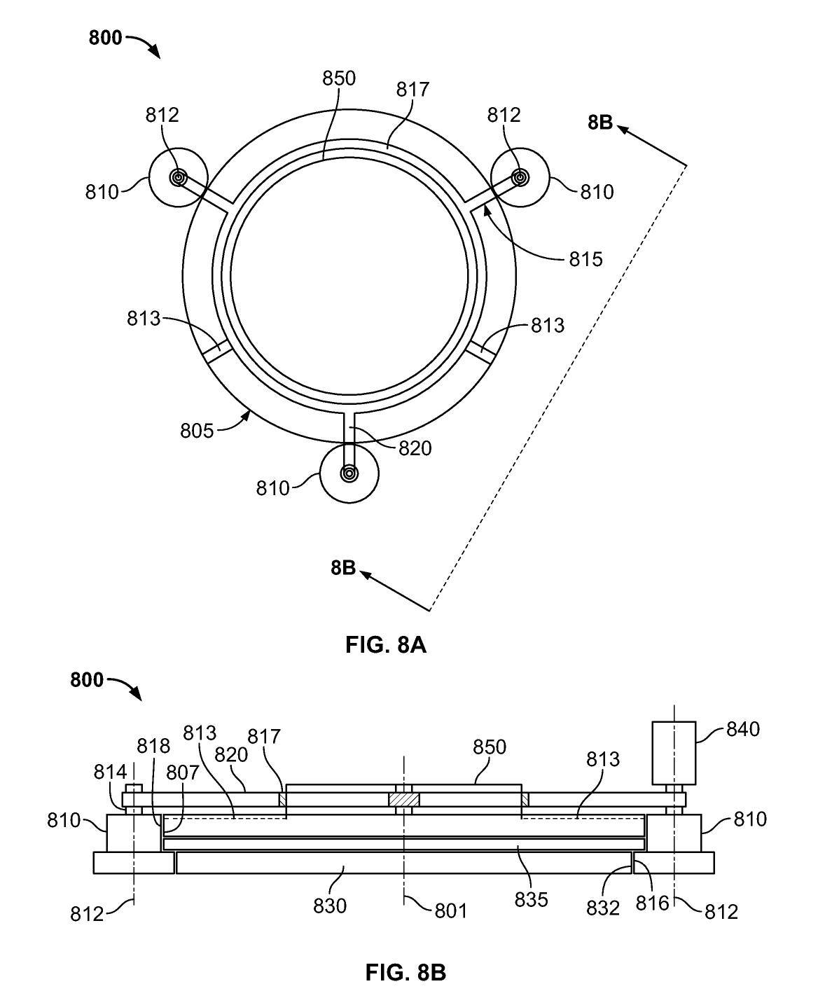

FIGS. 8A-8B illustrate top and side views of various components of another example embodiment of a drive assembly 800. The drive assembly 800 can be configured to rotate a solar energy member, such as the solar energy member 125 shown in FIG. 1, although the drive assembly 800 can also be used in other implementations. In some embodiments, the illustrated components of drive assembly 800 may be used in or with the drive assembly 115 shown in FIG. 1. Generally, the drive assembly 800 may receive a rotational torque at a first rotational speed and transform the first rotational speed to a second rotational speed according to a predetermined ratio. The second rotational speed, which in some embodiments may be less than, or much less than, the first rotational speed, may be applied to a rotor and/or shaft. The rotor and/or shaft may be coupled to, for example, a solar energy member in order to rotate the solar energy member at the second rotational speed.

As illustrated, the drive assembly 800 includes a cylindrical rotor 805 and a cylindrical stator 830 having centers coincident with a central axis 801; multiple planetary members 810 having respective planetary axes 812 arranged around respective circumferential surfaces of the rotor 805 and stator 830; and a spider assembly 815 coupled to the planetary members 810. The illustrated drive assembly 800 also includes a driver 840 coupled to one of the planetary members 840 and a bearing 835 disposed between the rotor 805 and the stator 830. The cylindrical rotor 805, cylindrical stator 830, planetary members 810, bearing 835, and driver 840 may be substantially similar to those components described above with respect to FIGS. 2A-2B.

As illustrated, each planetary member 810 includes an axle 814 disposed through the planetary axis 812 of the planetary member 810. In some implementations, the axle 814 may be sealed (e.g., hermetically) through the planetary member 810 such that moisture, dust, or other substance is substantially prevented from intrusion therein. In the implementation shown, the drive assembly 800 also includes a spider assembly 815. The spider assembly 815 includes spokes 820 coupled to axles 814 of the planetary members 810 and also coupled to a web member 817. The planetary members 810 may be rigidly or semi-rigidly held against the rotor 805 and stator 830 by the spokes 820.

As illustrated, the spider assembly 815 is free to rotate with respect to both the stator 830 and the rotor 805 about the central axis 801. The spider assembly 815, as illustrated, may fit over a shaft 850 that is coupled to the rotor 850 with little or no contact with the shaft 850. For example, the web member 817 may include an aperture therethrough that allows the shaft 850 to pass through the web member 817 with little or no contact. Thus, rotation of the spider assembly 815 may be decoupled from rotation of the rotor 805 (and shaft 850) such that the spider assembly 815 and rotor 805 may rotate at different speeds about the central axis 801.

As illustrated in FIG. 8B, the driver 840 is coupled to the axle 814 of one of the planetary members 810. While more than one of the planetary members 810 may be coupled to a driver (e.g., an electric motor) and driven (e.g., rotated) about its planetary axis 812, one driver 840 may be coupled to one planetary member 810 and utilized for operation of the drive assembly 800. In other implementations, there may be multiple drivers 840.

In operation, the driver 840 may rotate the planetary member 810 to which it is coupled, which in turn rotates the spider assembly 815. Alternatively, the driver may be configured to directly rotate the spider assembly 815 coupled to the planetary members 810, at a first rotational speed. In any event, the spider assembly 815 carries the planetary members 810 along as it rotates, keeping the planetary members 810 in firm contact with the rotor 805 and stator 830 (i.e., keeping contact between the upper planetary member surface 818 and rotor circumferential surface 807, and between the lower planetary member surface 816 and the stator circumferential surface 832). As the spider assembly 815 rotates about the central axis 801, the planetary members 810 also rotate about their own respective planetary axes 812 due to the rolling contact between the lower planetary member surface 816 and the fixed stator circumferential surface 832. As the planetary members 810 rotate, they are also in rolling contact with the rotor 805 and impart a torque to the rotor 810. Due to the difference in radial dimensions between rotor 805 and the stator 830 (Rr>Rs), the rotor 805 may be rotated with the rotation of the spider assembly 815, but at a second rotational speed that is substantially reduced compared to the first rotational speed. Further, the rotor 805 may be rotated with a substantially-multiplied torque. The net result is an effective gear ratio, with the spider assembly 815 serving as an input and the rotor 805 serving as an output. While not shown, a shaft rigidly coupled to the rotor 805 will thus rotate at the second rotational speed as well. Further, any structure rigidly coupled to the shaft (directly or indirectly), such as a solar energy member, will also rotate at the second rotational speed.

As illustrated, in FIG. 8A, the rotor 820 includes two fluid conduits 813 disposed on an upper surface of the rotor 805. In some embodiments, the fluid conduits 813 may be weep channels, funneling liquid and other debris away from the central axis 801 and towards the rotor circumferential surface 807. For example, in some embodiments, the drive assembly 800 (like other illustrated drive assemblies disclosed herein) may be exposed to an outdoor environment during operation. For instance, all or part of the rotor 805, the stator 830, the planetary members 810, and other components of the drive assembly 800 may operate without any enclosure while exposed to, for example, rain, snow, sleet, and other environmental elements. In some aspects, the only portions of the drive assembly 800 that may be sealed (substantially or completely) against the outdoor environment are the axles 814 disposed through the planetary members 810. During periods of inclement weather during operation of the drive assembly, moisture, such as rain, snow, or sleet, may accumulate on the upper surface of the rotor 805. Such moisture may gather (e.g., by a graded surface on the upper surface of the rotor 805) in the fluid channels 813 and ultimately may be funneled off the rotor 805. Further, debris within the fluid and other debris, such as dirt, sand, and other debris, may also be funneled off the rotor 805 by the fluid channels 813. In some embodiments, the fluid channels 813 may slope away from the central axis 801 and towards the rotor circumferential surface 807.

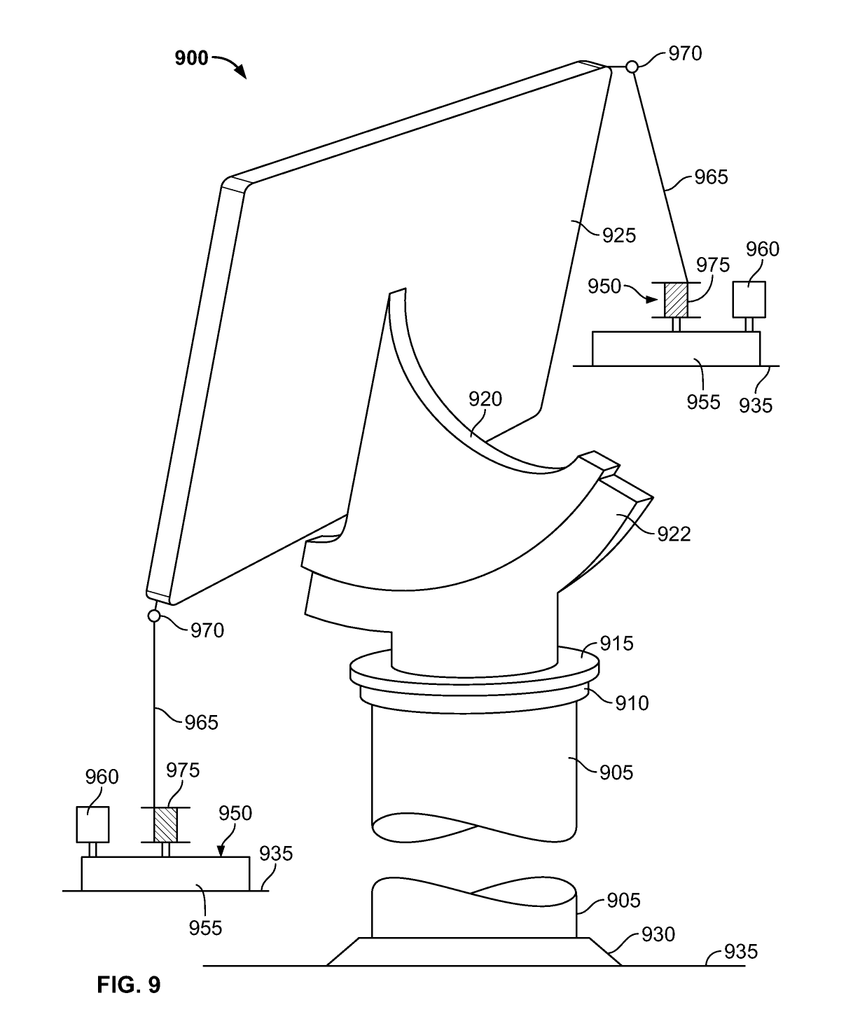

FIG. 9 illustrates another example embodiment of a solar energy system 900 including a drive assembly for rotating a solar energy member 925. In the illustrated embodiment, the solar energy system 900 includes a support member 905, a base 910 mounted on the support member 905, a azimuthal bearing 915 mounted on the base 910, a solar energy member support 920 mounted on the azimuthal bearing 915 via an interface 922, and a solar energy member 925 coupled to the solar energy member support 920. The support member 905, base 910, solar energy member support 920, interface 922, and solar energy member 925 may be substantially similar to those same components described above with reference to FIG. 1.

Solar energy system 900, as illustrated, may collect or reflect solar energy from a mote source (e.g., the Sun or other solar energy source) while rotatably tracking the source under varying environmental conditions. For example, in some embodiments, the solar energy system 900 may be a heliostat that tracks (e.g., rotates to change its azimuth and/or pivots to change its elevation) the Sun in order to receive and reflect solar energy from the Sun to a solar energy collector (receiver) located remote from the heliostat. Alternatively, the solar energy system 900 may be a PV system where the solar energy member 925 is a PV panel that tracks the Sun to receive and collect solar energy to, for example, produce electricity. In any event, in some instances, the solar energy system 900 may be one of many systems 900 installed within a field or array that operate to collect and/or reflect solar energy provided by the remote source.

The solar energy member 925 is mounted to the support 920 such that rotation about the azimuthal axis and rotation about the elevational axis within desired ranges to account for tracking the Sun throughout the course of day and throughout the days of a year are permitted. For example, in some implementations, a bearing at the interface 922 can operate to facilitate reduced friction rotation of the solar energy member 925 about the elevational axis. Further, the azimuthal bearing 915 may operate to facilitate reduced friction rotation of the solar energy member 925 about the azimuthal axis.

System 900 includes one or more drive assemblies 950 that operate to exert a force on the solar energy member 925 in order to, for instance, rotate the member 925 about one or both of the azimuthal and elevational axes. As illustrated, two drive assemblies 950 are coupled to eye-hooks 970 of the solar energy member 925 via cables 965. Alternatively, more or fewer drive assemblies 950 may be used. Further, although illustrated as coupled to corners of the solar energy member 925, the drive assemblies 950 may be coupled to other portions of the solar energy member 925 in addition to, or rather than, the corners. Moreover, while illustrated as mounted on a terranean surface 925, the one or more drive assemblies 950 may be mounted in other locations while still coupled to the solar energy member 925. For instance, the drive assemblies 950 may be mounted to the solar energy member 925 itself and coupled to the terranean surface 935 via the cables 965. One or more of the drive assemblies 950 may be substantially similar to one of the foregoing drive assemblies described above.

In the illustrated embodiment, the solar energy member 925 may be a heliostat mirror, which receives and reflects solar energy incident on a surface of the member 925 toward a remote location, such as a solar energy receiver. Alternatively, however, the solar energy member 925 may be another solar energy device, such as a PV panel. In any event, the solar energy member 925, typically, is substantially planar or can be curved and includes at least one surface that receives and reflects (i.e., a heliostat mirror) or receives and absorbs (i.e., a PV panel) solar energy. Although illustrated in FIG. 9 as a single, monolithic panel, the solar energy member 925 may be split into two (or more) equally or unequally-sized panels that together form the solar energy member 925.

The drive assemblies 950 may be substantially similar to one or more of the drive assemblies described with reference to FIGS. 2A-2B, 3, 4, 5A-5B, and 8. As illustrated, the drive assemblies 950 also include a driver 960 that, as described above, may ultimately rotate a shaft rigidly coupled to a rotor of the drive assembly 950 at a predetermined gear ratio. Each of the illustrated drive assemblies 950 include a spool 975 coupled to the shaft of the drive assembly 950. The spool 975 may rotate at the same angular speed as the shaft in order to reel in the cable 965 and/or release additional cable 965. As the cable 965 is reeled in and/or released, the solar energy member 925 may be rotated (e.g., azimuthally and/or elevationally) a particular amount depending on the length of cable 965 that is reeled in and/or released.

In operation, one or both of the drive assemblies 950 may receive a command to rotate the solar energy member 925 and/or determine that the solar energy member 925 should be moved (e.g., to track the position of the Sun). The driver 960 may then be powered to rotate one or more components of the drive assembly 950, such as, for example, one or more planetary members, a harness assembly, a spider assembly, or a plate, as described above. Rotation of the driver 960 ultimately rotates a rotor of the drive assembly 950 that is rigidly coupled with the spool 975. As the spool 975 rotates, the cable 965 reels in or is released, depending on the rotational direction of the spool 975. If the cable 965 is reeled in, tension is exerted on the cable 965 and pulls the solar energy member 925 towards the drive assembly 950. The solar energy member 925 therefore rotates about one or both of the azimuthal or elevational axes depending on the position of the drive assembly 950. If the cable 965 is released, tension is released on the cable 965 and the solar energy member 925 may, for example, rotate towards a default position (e.g., due to a biasing force) and/or rotate due to tension placed on the solar energy member 925 due to another drive assembly 950. The solar energy member 925 therefore rotates about one or both of the azimuthal or elevational axes depending on the position of the drive assembly 950. Rotation is facilitated by the azimuthal bearing 915 and/or the elevational bearing of the interface 922.

In some embodiments, two or more drive assemblies 950 may operate in concert to rotate the solar energy member 925. For example, in order to rotate the solar energy member 925 about the azimuthal axis, one or more drive assemblies 950 may operate to release cable 965 towards the solar energy member 925 while another drive assembly 950 (or multiple assemblies) may operate to reel in cable 965. Further, although two drive assemblies 950 are illustrated in FIG. 9, there may be more or fewer drive assemblies. Moreover, in some embodiments, certain drive assemblies 950 may operate to rotate the solar energy member 925 about the azimuthal axis while other drive assemblies 950 may operate to rotate the solar energy member 925 about the elevational axis independent of the azimuthal rotation.

A number of implementations have been described. Nevertheless, it will be understood that various modifications may be made. For example, while some embodiments have been described and/or illustrated in terms of heliostats, other solar energy members, such as PV panels, may also be utilized in accordance with the present disclosure. In addition, a controller of a solar energy system, such as the first controller 635 and/or the second controller 640 of the solar energy system 600, may be operable to control a motor at a particular angular speed while compensating for slippage in a planetary gear drive that uses friction (as opposed to all-geared) components. Further, method 700 may include less steps than those illustrated or more steps than those illustrated. In addition, the illustrated steps of method 700 may be performed in the order illustrated or in different orders than that illustrated.

As another example, while certain embodiments of a drive assembly illustrated herein include a rotor mounted above a stator, other embodiments of a drive assembly may have a stator mounted above (i.e., on top of) a rotor. Further, while the illustrated embodiments of a drive assembly include a rotor with a larger radial dimension than a stator, other embodiments may include a stator with a larger radial dimension than a rotor. In such embodiments, the value E in equation (2) is negative and then the rotation of the (smaller) rotor will be in the opposite rotational direction as the planetary members of the drive assembly.

As another example, in some embodiments, a drive assembly (such as the drive assemblies 200, 300, 400, 500, 800, and otherwise) may include a feedback system to provide feedback on a position of a solar energy member, such as a heliostat mirror or PV cell. For example, the feedback system may provide a drive assembly (e.g., a controller or other processor of a drive assembly) signals or data regarding a pointing angle (e.g., elevational or azimuthal) of the solar energy member. The drive assembly may then operate to correct the pointing angle by, for instance, moving the solar energy member that is coupled to the drive assembly. For example, certain drive assemblies may utilize frictional contact between certain components, such as between one or more planetary members and a rotor and stator. In such systems (and others), there may be backlash or slippage, among other issues, thereby making a gear ratio imprecise. Moreover, after significant use of such components, wear and tear may increase or cause slippage, thereby further exacerbating the issue. In such cases, the feedback system may ensure that the drive assembly operates to move the solar energy member to a desired or correct pointing angle (elevational and/or azimuthal). In one aspect, the feedback system may include a laser reader or scanner operable to detect one or more markings or pattern engraved or marked on an upper surface of the rotor. Through operation of the laser scanner, the feedback system may more precisely determine the pointing angle of the solar energy member coupled to the rotor and control the drive assembly accordingly. In another aspect, the feedback system may include a sensor located at a solar energy receiver, which measures solar energy intensity reflected toward the receiver by one or more solar energy members. Based on the measured solar energy intensity, the feedback system may determine whether the pointing angle of the solar energy member is optimal and control the drive assembly (e.g., to move the solar energy member) accordingly. These two aspects may be combined, of course, and other types or techniques for feedback systems may be utilized, as appropriate. Accordingly, other implementations are within the scope of the following claims.

What is claimed is:

1. A solar energy system, comprising:
a solar energy member having a first surface facing toward the Sun, wherein solar rays from the Sun are incident on the first surface;
a drive assembly coupled to the solar energy member, the drive assembly comprising:
a rotor comprising a first circumferential surface and having a first radial dimension from a center axis at a center of the rotor;
a stator that is axially aligned with the rotor about the center axis, the stator comprising a second circumferential surface and having a second radial dimension from the center axis, wherein the second radial dimension is different than the first radial dimension;
a plurality of planetary members arranged about the first and second circumferential surfaces of the rotor and stator respectively, wherein each of the planetary members has a stepped circumferential surface comprising a third surface and a fourth surface such that the third circumferential surface is in contact with the first circumferential surface and has a third radial dimension from a central planetary axis of the planetary member; and the fourth circumferential surface is in contact with the second circumferential surface and has a fourth radial dimension from the planetary axis of the planetary member that is different than the third radial dimension; and
a driver configured to rotate the plurality of planetary members about the center axis, wherein each planetary member rotates about the member's planetary axis through contact between the second circumferential surface of the stator and the fourth circumferential surface of the planetary member and wherein said rotation of the planetary members imparts rotation of the rotor about the center axis through contact between the third circumferential surfaces of the planetary members and the first circumferential surface of the rotor; and
a controller configured to control movement of the solar energy member with the drive assembly in accordance with movement of the Sun.

2. The system of claim 1, wherein the first surface of the solar energy member is a reflective surface configured to reflect the solar rays toward a solar energy receiver.

3. The system of claim 1, wherein the first surface of the solar energy member is a solar panel that includes one or more photovoltaic cells.

4. The system of claim 1, wherein the controller is configured to control at least one of azimuthal movement of the solar energy member and elevational movement of the solar energy member.

5. The system of claim 1, wherein the drive assembly is a first drive assembly configured to adjust position of the solar energy member in azimuth in response to commands received from the controller, the system further comprising a second drive assembly substantially identical to the first drive assembly and configured to adjust a position of the solar energy member in elevation in response to commands received from the controller.

6. The system of claim 1, wherein at least a portion of the drive assembly is exposed to an outside environment during normal operation.

7. The system of claim 1, wherein the drive assembly further comprises a spool coupled to the rotor, the system further comprising:
a cable coupled to the spool at a first end and coupled to the solar energy member at a second end opposite the first end,
wherein rotation of the rotor about the center axis causes rotation of the spool to effect one of reeling in a portion of the cable around the spool or releasing a portion of the cable from the spool such that the solar energy member is rotated based on the rotation of the spool.

8. The system of claim 1, wherein the controller is configured to control the driver at a first angular speed to compensate for slippage between at least one of a frictional contact between the third circumferential surface and the first circumferential, and a frictional contact between the fourth circumferential surface and the second circumferential surface.

9. A drive apparatus, comprising:
a rotor comprising a first circumferential surface and having a first radial dimension from a center axis of the rotor;
a stator that is axially aligned with the rotor about the center axis, the stator comprising a second circumferential surface and having a second radial dimension from the center of the rotor, wherein the second radial dimension is different than the first radial dimension;
a plurality of planetary members arranged about the first and second circumferential surfaces of the rotor and stator respectively, wherein each of the planetary members has a stepped circumferential surface comprising a third surface and a fourth surface such that the third circumferential surface is in contact with the first circumferential surface and has a third radial dimension from a central planetary axis of the planetary member; and the fourth circumferential surface is in contact with the second circumferential surface and has a fourth radial dimension from the planetary axis of the planetary member that is different than the third radial dimension; and
a driver configured to rotate the plurality of planetary members about the center axis, wherein each planetary member rotates about the member's planetary axis through contact between the second circumferential surface of the stator and the fourth circumferential surface of the planetary member and wherein said rotation of the planetary members imparts rotation of the rotor about the center axis through contact between the third circumferential surfaces of the planetary members and the first circumferential surface of the rotor.

10. The apparatus of claim 9, wherein at least one of the contact between the second circumferential surface of the stator and the fourth circumferential surface of the planetary member, and the contact between the third circumferential surfaces of the planetary members and the first circumferential surface of the rotor comprises frictional contact.

11. The apparatus of claim 9, wherein at least one of the contact between the second circumferential surface of the stator and the fourth circumferential surface of the planetary member and the contact between the third circumferential surfaces of the planetary members and the first circumferential surface of the rotor comprises geared contact.

12. The apparatus of claim 9, wherein the driver is coupled to at least one of the planetary members.

13. The apparatus of claim 9, further comprising a harness assembly comprising:
at least one substantially rigid member connecting axles disposed through respective centers of two planetary members; and
a biasing member connecting axles disposed through respective centers of two planetary members, wherein the biasing member urges the axles together.

14. The apparatus of claim 13, wherein the driver is coupled to the harness assembly and configured to rotate the harness assembly about the center axis to rotate the planetary members about the center axis.

15. The apparatus of claim 13, wherein the biasing member comprises a spring.

16. The apparatus of claim 13, wherein the harness assembly comprises first and second plates having centers aligned with the center axis, and wherein the rotor and stator are sandwiched between the first and second plates.

17. The apparatus of claim 16, wherein at least one of the first and second plates comprise a circumferential surface having a geared surface.

18. The apparatus of claim 17, further comprising a gear coupled to the driver and interfacing the geared surface, wherein the gear is configured to transfer rotational force from the driver to the one of the first and second plates through the geared surface.

19. The apparatus of claim 16, wherein the one of the first and second plates comprises a circumferential surface in frictional contact with the planetary member such that rotation of the plate causes rotation of the planetary member about the member's central planetary axis.

20. The apparatus of claim 9, wherein the plurality of planetary members comprise three planetary members.

21. The apparatus of claim 9, wherein at least one of the rotor or stator is comprised of a formed concrete disk.

22. The apparatus of claim 9, wherein at least one of the rotor or stator contact surfaces comprises a tire tread.

23. The apparatus of claim 9, wherein the driver comprises an electric motor.

24. The apparatus of claim 9, wherein the second radial dimension is smaller than the first radial dimension by a predetermined differential, and the fourth radial dimension is larger than the third radial dimension by the predetermined differential.

25. The apparatus of claim 9, wherein the first radial dimension is smaller than the second radial dimension by a predetermined differential, and the third radial dimension is larger than the fourth radial dimension by the predetermined differential.

26. The apparatus of claim 24, wherein:
the predetermined differential is approximately 0.1 inches;
the third radial dimension is approximately 3 inches; and
the second radial dimension is between approximately 24 inches and approximately 36 inches.

27. The apparatus of claim 9, further comprising a bearing disposed between the rotor and the stator.

28. The apparatus of claim 9, further comprising a spider assembly comprising:
multiple spokes coupled to axles disposed through respective centers of two planetary members; and
a web member coupled to the spokes and comprising an aperture operable to allow a shaft rigidly coupled to the rotor to pass through.

29. A drive apparatus, comprising:
a rotor comprising a first circumferential surface and having a first radial dimension from a center axis of the rotor;
a stator that is axially aligned with the rotor about the center axis, the stator comprising a second circumferential surface and having a second radial dimension from the center of the rotor, wherein the second radial dimension is different than the first radial dimension;
a plurality of planetary members arranged about the first and second circumferential surfaces of the rotor and stator respectively, wherein each of the planetary members has an outer surface in contact with the first and second circumferential surfaces; and
a driver configured to rotate the plurality of planetary members about the center axis, wherein each planetary member rotates about the member's planetary axis through contact between the second circumferential surface of the stator and the outer surface of the planetary member and wherein the rotation of the planetary members imparts rotation of the rotor about the center axis through contact between the outer surfaces of the planetary members and the first circumferential surface of the rotor,
wherein at least a portion of at least one of the plurality of planetary members is adapted to be substantially sealed against an outside environment during normal operation of the apparatus, and at least a portion of at least one of the rotor and stator are adapted to be exposed to the outside environment during normal operation of the apparatus.

30. The apparatus of claim 29, wherein at least one of the planetary members comprises an axle such that a portion of the axle is disposed through a bore of the planetary member, and the portion of the planetary member adapted to be substantially sealed against the outside environment comprises the portion of the axle disposed through the bore.

31. The apparatus of claim 29, wherein the stator is axially aligned with the rotor about the center axis such that the stator is mounted adjacent a bottom surface of the rotor.

32. The apparatus of claim 31, wherein the first radial dimension from the center axis of the rotor is greater than the second radial dimension from the center of the rotor.

33. The apparatus of claim 31, wherein the rotor includes a conduit disposed on an upper surface of the rotor adapted to direct a flow of fluid away from the center of the rotor.

34. The apparatus of claim 29, wherein at least one of the contact between the second circumferential surface of the stator and the outer surfaces of the planetary members, and the contact between the first circumferential surface of the rotor and the outer surfaces of the planetary members comprises frictional contact.

35. The apparatus of claim 29, wherein at least one of the rotor and stator is constructed of a moisture resistant material.

36. The apparatus of claim 29, wherein all of the rotor and the stator are adapted to be exposed to the outside environment during normal operation of the apparatus.
